(19) United States
(12) Patent Application Publication
(10) Pub. No.: US 2020/0101481 A1
(43) Pub. Date: Apr. 2, 2020

(54) THERMOELECTRIC IRRIGATION MODULE AND METHODS OF USE THEREOF

(71) Applicant: COLORADO SCHOOL OF MINES, Golden, CO (US)

(72) Inventors: Salman Mohagheghi, Golden, CO (US); Jamison Alan Olsten, Golden, CO (US)

(21) Appl. No.: 16/584,091

(22) Filed: Sep. 26, 2019

Related U.S. Application Data
(60) Provisional application No. 62/737,857, filed on Sep. 27, 2018.

(51) Int. Cl. B05B 12/12; H01L 35/32; H01L 35/02; G05B 13/02

(52) U.S. Cl. CPC B05B 12/12; G05B 13/024; H01L 35/02; H01L 35/32

(57) ABSTRACT

Disclosed herein are systems and techniques for controlling irrigation systems using thermoelectric devices. A thermoelectric generator can produce a voltage that is proportional to a temperature differential measured locally, adjacent an irrigation target or sprinkler. The voltage can be used to control the irrigation sprinkler, for example, by providing a signal to a control valve that is fluidly coupled with the sprinkler. The system can be self-contained, without external electrical connections and without solar panels, allowing for remote use that is not dependent upon solar irradiance. The system can further be tuned to individually control irrigation components, such as by calibrating the voltage to soil moisture or other conditions, and actuating the valve when the voltage reaches a threshold indicative of the condition.

### CROSS-REFERENCE TO RELATED APPLICATIONS

This patent application is a non-provisional patent application of, and claims priority to, U.S. Provisional Application No. 62/737,857 filed Sep. 27, 2018, and titled “Thermoelectric Irrigation Module”, the disclosure of which is hereby incorporated by reference in its entirety.

### FIELD

The described embodiments relate generally to thermoelectric devices. More particularly, the present embodiments relate to systems and techniques for adapting thermoelectric devices for use in irrigation and associated systems.

### BACKGROUND

Irrigation systems can include two or more irrigation sprinklers distributed across a remote location, such as a golf course, agricultural field, a residential lawn, municipal building grounds, and so on. Traditional systems for controlling sprinklers can include providing a power source to each sprinkler, such as via dedicated solar panels and/or hardwired connections. These traditional approaches can increase complexity and hinder system reliability. Traditional approaches often provide no information pertaining to ambient conditions associated with the soil. As such, the need continues for improved approaches for powering irrigation-related components, and providing information associated with ambient conditions.

### SUMMARY

Embodiments of the present invention are directed to thermoelectric devices that can be adapted to control features of an irrigation system. The disclosed thermoelectric devices are generally configured for exposure to a temperature differential, and to use the temperature differential to generate a voltage. The voltage can be used to control an irrigation sprinkler or other features, such as by opening or closing a valve switch of the sprinkler based on local measurements. These measurements could be of the ambient temperature, soil temperature, soil humidity, etc. The disclosed device can be self-powered and does not need to have on-board battery units (however, some embodiments may include battery units, including rechargeable battery units). As opposed to traditional approaches, the disclosed devices can be used without solar panels, so they are not dependent on exposure to direct sunlight. The devices can be activated or triggered based on humidity of the soil, without a need for additional humidity sensors.

Use of the disclosed devices can help save water, and can be beneficial in areas affected by drought and/or high heat (or heat waves). This can be achieved because watering can be done based on the status of the soil (temperature and moisture) or the environment (ambient temperature). As a result, overwatering or pre-scheduled watering after periods of rain will be avoided. Residential homes, commercial green spaces, and golf courses can benefit from the disclosed devices and systems. In addition, the disclosed devices and systems can be used in agriculture, for example with irrigation systems for vineyards, farms, orchards and specialty crops. State and Federal organizations and water utilities can recognize and take advantage of benefits offered by these devices, especially in regions regularly affected by drought and water shortage.

The disclosed devices can allow for implementing a customized, intelligent and decentralized water irrigation system. Using the disclosed devices can make it possible for individual sprinkler heads or other irrigation outlets to be turned on and off based on localized ambient temperature, soil temperature, and/or soil humidity, in many cases, without installing additional sensors. The devices can be “tuned,” prior to installation so that it triggers (e.g., turns on/off) based on user preferences for individual watering zones.

While many examples are described herein, in an embodiment, a device for remotely and automatically operating a valve is disclosed. The device includes a thermoelectric generator (TEG). The device further includes a heat absorption unit. The device further includes a heat sink. The device further includes a control circuit. The device can further include and/or be operably coupled with a switch operably connected to the valve.

In another embodiment, the TEG, control circuit, and switch can be electrically connected. Further, the TEG, absorption unit, and heat sink can be thermally connected. The valve can be fluidly connected to an irrigation sprinkler.

In another embodiment, the TEG comprises N- or P-type semiconductors. In some cases, the N- or P-type semiconductors can be connected in parallel.

In another embodiment, the heat absorption unit can be selected from one or more of a lens or a mirror for concentrating solar radiation on a hot side of the TEG. The heat absorption unit can include a black hollow sphere fitted around the TEG for absorbing visible and non-visible light. Additionally, the heat sink can include a rod configured to be inserted into soil. The rod can be a metal rod, as described herein.

In another embodiment, the device further includes a battery electrically connected to the TEG, for storing electricity.

In another embodiment, a method for controlling a valve is disclosed. The method includes arranging a thermoelectric generator (TEG) adjacent soil that is associated with a valve. The method further includes electrically connecting the TEG to a valve switch fluidly connected to the valve. The method further includes controlling the valve using a signal generated by the TEG.

In an embodiment, the method can further include exposing the TEG to a temperature differential. The method can further include generating a voltage using the temperature differential In this regard, the signal can be based at least in part on the generated voltage.

In another embodiment, the method can further include inserting a heat sink into the soil, the heat sink thermally coupled to the TEG. The TEG can thus be thermally connected to a heat absorption unit. In this regard, the temperature differential can be defined between the heat sink and the heat absorption unit.

In another embodiment, the controller can be positioned between the TEG and valve switch, and in electrical communication with the TEG and valve switch. The valve can be in fluid connection with an irrigation sprinkler.

In another embodiment, a controller can be wirelessly connected to multiple TEG devices and generates a pulse for the valve switch based on the collective information received from multiple TEGs.

In another embodiment, a method for measuring soil moisture is disclosed. The method includes arranging a thermoelectric generator (TEG) adjacent the soil. The method further includes exposing the TEG to a temperature differential. The method further includes generating a voltage using the temperature differential. The method further includes determining a moisture content of the soil using the generated voltage and an ambient temperature associated with the soil.

In another embodiment, the operation of determining can include calibrating the voltage to the moisture content using a linear or non-linear regression. In this regard, the moisture content can be a function of the generated voltage and the ambient temperature.

In another embodiment, the method can include transmitting a signal including information associated with the moisture content to a remote device.

In another embodiment, the method can include thermally associating the TEG with a heat sink arranged at least partially within the soil. The TEG includes a heat absorption unit arranged opposite the heat sink. The temperature differential can be defined between the heat sink and the heat absorption unit.

In addition to the exemplary aspects and embodiments described above, further aspects and embodiments will become apparent by reference to the drawings and by study of the following description.

### BRIEF DESCRIPTION OF THE DRAWINGS

The disclosure will be readily understood by the following detailed description in conjunction with the accompanying drawings, wherein like reference numerals designate like structural elements, and in which:

FIG. 1 depicts a sample outdoor environment having thermoelectric devices;

FIG. 2 depicts a functional diagram of a thermoelectric system;

FIG. 3 depicts another functional diagram of a thermoelectric system;

FIG. 4 depicts another functional diagram of a thermoelectric system and associated irrigation assembly;

FIG. 5 depicts an embodiment of a thermoelectric module;

FIG. 6 depicts another embodiment of a thermoelectric module;

FIG. 7 depicts another embodiment of a thermoelectric module;

FIG. 8 depicts another embodiment of a thermoelectric module;

FIG. 9 depicts another embodiment of a thermoelectric module;

FIG. 10 depicts a flow diagram for controlling a valve; and

FIG. 11 depicts a flow diagram for measuring soil moisture.

The use of cross-hatching or shading in the accompanying figures is generally provided to clarify the boundaries between adjacent elements and also to facilitate legibility of the figures. Accordingly, neither the presence nor the absence of cross-hatching or shading conveys or indicates any preference or requirement for particular materials, material properties, element proportions, element dimensions, commonalities of similarly illustrated elements, or any other characteristic, attribute, or property for any element illustrated in the accompanying figures.

Additionally, it should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various examples described herein and, accordingly, may not necessarily be presented or illustrated to scale, and are not intended to indicate any preference or requirement for an illustrated example to the exclusion of examples described with reference thereto.

### DETAILED DESCRIPTION

The description that follows includes sample systems, methods, and apparatuses that embody various elements of the present disclosure. However, it should be understood that the described disclosure may be practiced in a variety of forms in addition to those described herein.

The present disclosure describes systems, devices, and techniques related to thermoelectric devices adapted for use in controlling irrigation and associated systems typically used in an outdoor environment. A thermoelectric device can include a thermoelectric generator (“TEG”, also referred to herein as a “TEG module”) that is adapted to generate a voltage when exposed to a temperature differential. For example, the TEG module can be exposed to a temperature differential in an outdoor environment, such as a temperature differential between soil and an ambient atmosphere, and generate a voltage in response to the temperature differential. The voltage generated by the TEG module can be used to control one or more features of an irrigation system, such as an irrigation sprinkler and/or otherwise be adapted to provide information associated with the environment, such as information corresponding to a moisture of the soil, as described herein. Irrigation system features are often remote, dispersed, or otherwise not readily or practicably individually controllable, and thus irrigation systems can be susceptible to inappropriately providing water based on a standardized or pre-set schedule not adaptable for ambient conditions.

The TEG module of the present disclosure can mitigate such hindrances by providing a localized power source to individual irrigation system features, such as an irrigation sprinkler. Without the need for hard wired connections, solar panels, batteries, or other electrical power-providing devices, many (or all) of the features of an irrigation system can be individually controlled in a reliable manner. And the individual control of the irrigation system feature can help tune the features for specific environmental conditions, such as providing more or less water based on an ambient temperature, a soil temperature, soil moisture, and so on, including tuning the irrigation features based on other data, which can be remotely controlled or provided. And in some cases, as described herein, the TEG module itself can provide the data for controlling the irrigation features in addition to (or alternatively to) providing a power supply to the irrigation features, including where the TEG module functions as a moisture sensor, and the irrigation system feature is controlled based on the moisture of the soil.

To facilitate the foregoing, the TEG module can include a device that implements a number of N-type and P-type semiconductors that are electrically connected to series and thermally connected in parallel. This arrangement can leverage the Seebeck effect, in which an exposure to a temperature difference ΔT allows the device to generate a voltage that is proportional to the temperature difference. The TEG module can be associated with or include various structural features to facilitate establishing and maintaining a sufficient temperature difference to generate a threshold or target voltage. For example, in one embodiment, the TEG module can include a heat absorption unit that can be thermally associated with a “hot” side of the TEG module, including a lens, concentric mirror, black hollow sphere or other features that can absorb and generally concentrate heat for delivery to the hot side of the TEG module. Additionally or alternatively, the TEG module can include a heat sink that can be associated with a “cold” side of the TEG module, including a rod or plate or other features that can be used to move heat away from the TEG module and into a cooling source, such as a cooler subsurface soil. The rod or plate can be formed from a metal material. In this regard, the heat absorption unit and the heat sink can cooperate to increase a temperature differential experienced by the TEG module, thus facilitating a higher and potentially more consistent voltage generation for irrigation system feature control; however, this is not required.

In certain embodiments, the TEG module can be used to control the operation of an irrigation system feature using generated voltage. As an illustration, irrigation system features can include an irrigation valve fluidly connected to a fluid source, and the operation of the irrigation valve can be controlled by a valve switch. The TEG module can generally send a signal to the valve switch in order to control the flow of fluid from the fluid source through the irrigation valve, including opening, closing and/or throttling fluid therethrough. As such, the systems and techniques described herein can include a control circuitry, such as a controller that can be responsible for generating a control command for opening or closing or throttling the valve switch, using the voltage generated by the TEG module. The controller can perform other functions, including amplifying and tuning certain signals to effect the appropriate valve operation. In some cases, the controller can also be adapted to include and/or be associated with an antenna or other communication device adapted to send and receive signals with a remote computing system. In this regard, the irrigation sprinkler can be controller in response to remote commands, using the power generated locally, adjacent the irrigation sprinkler with the TEG module.

The voltage generated by the TEG module can also be used to trigger operation of the irrigation sprinkler, based on local conditions. For example, as the temperature differential increases between the hot and cold sides of the TEG module, the TEG module can generally generate a proportionally larger voltage. The controller can receive the generated voltage and actuate the valve switch in response to the value of the generated voltage meeting or exceeding a threshold or set-point value. The threshold valve can be tuned and calibrated in order to provide water via the irrigation sprinkler in response to certain conditions. To illustrate, certain temperature differentials can be the result of low soil moisture, and thus indicative of the soil needing a quantity of water or other nourishments, such as one of many other calibration schemes, as contemplated and described herein. Correspondingly, when the temperature differential drops and the voltage drops below the threshold or set-point, which can correspond to conditions associated with sufficiently moist soil, the controller can close or otherwise manipulate the valve switch to cease water flow through the irrigation sprinkler.

It will be appreciated that the TEG modules of the present disclosure need not be accompanied by the controller or irrigation system features. For example, the TEG module can be implemented in a number of environments in order to provide information associated with local ambient conditions, and/or provide power to remote or otherwise distributed devices, without necessarily the need for hardwired connections, batteries, solar panels, and so on. As one example, the TEG module can be implemented in an outdoor environment as a moisture sensor, helping to detect soil conditions. For example, the amount of voltage generated by the TEG module can be calibrated to indicate the moisture content of the soil, such as the soil surrounding the module. As described in greater detail herein, linear and non-linear regressions can be used to calibrate the TEG module, and communicate the relationship between moisture, temperature, and voltage. This information can be transmitted to a remote computing center for processing and optionally controlling other devices, including those of an irrigation system that are not necessarily directly electrically connected to the TEG module. In other configurations, other adaptations and uses of the TEG module are possible, including using the TEG module to charge a rechargeable battery, as may appropriate for a given application. For example, the rechargeable battery can be associated with the irrigation system and used to power irrigation valves subsequent to the generation of voltage by the TEG module. This can be beneficial, for example, when the irrigation system or other electrical component is arranged to operate during times with a lower thermal differential.

Reference will now be made to the accompanying drawings, which assist in illustrating various features of the present disclosure. The following description is presented for purposes of illustration and description. Furthermore, the description is not intended to limit the inventive aspects to the forms disclosed herein. Consequently, variations and modifications commensurate with the following teachings, skill, and knowledge of the relevant art are within the scope of the present inventive aspects.

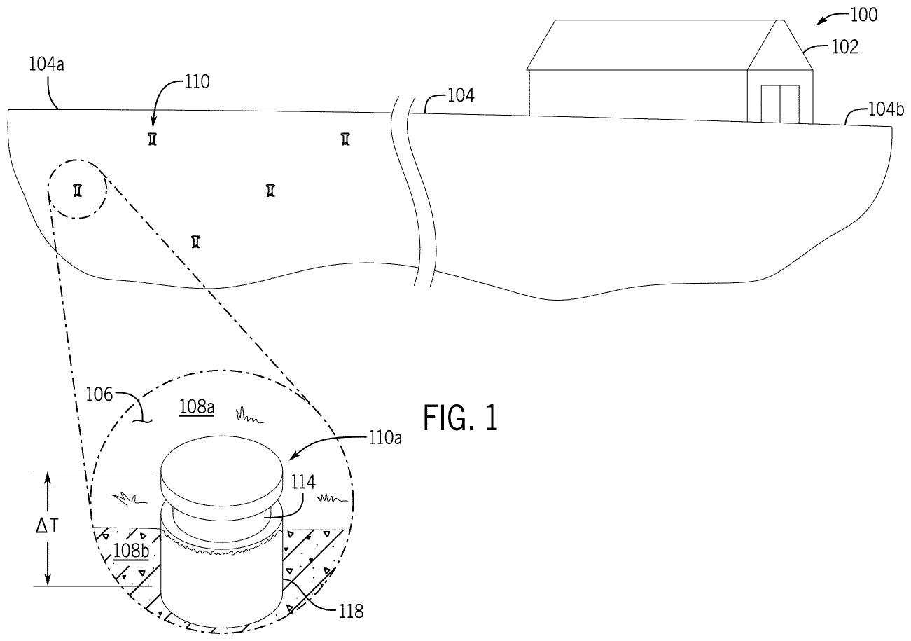

FIG. 1 depicts a sample outdoor environment having thermoelectric devices, such as the thermoelectric devices discussed above and described in greater detail below. For example, an environment 100 is shown. The environment 100 can be an outdoor environment or other environment which can benefit from irrigation. The environment 100 can exhibit temperature changes that can be utilized by thermoelectric devices to control one or more features of the environment or irrigation system. In this regard, the environment 100 is shown as including a group of thermoelectric devices 110 that are arranged relative to soil 104. The soil 104 can be associated with a variety of uses that benefit from irrigation, including residential home lawns and gardens, commercial green spaces, golf courses, and can even include certain agricultural uses, such as vineyards, farms, orchards, and specialty crops.

The group of thermoelectric devices 110 can be arranged in a first soil portion 104a which can be remote or removed from a second soil portion 104b. The second soil portion 104b can be associated with a structure 102 or other facility that can generally have ready access to a power supply, such as being connected to a local power grid. However, because the first soil portion 104a can be remote from the second soil portion 104b, the group of thermoelectric devices 110, irrigation sprinklers, or other features associated with the first soil portion 104a may not be electrically connected or connectable to the power supply associated with the structure 102. Accordingly, the group of thermoelectric devices 110 can be integrated with the soil 104 in order to produce a voltage that can be used to power and control devices and features of the environment 100, such as irrigation sprinklers associated with the first soil portion 104a.

To illustrate the foregoing, FIG. 1 shows a thermoelectric generator (TEG) module 110a. The TEG module 110a can be a representative one of the group of thermoelectric devices 110. The TEG module 110a is integrated with the first soil portion 104a in order to generate voltage and or more generally provide information associated with an irrigation target 106. The irrigation target 106 can be grass, flowers, crops, or substantially any other feature of the environment 100 that can benefit from irrigation and/or which a potential user desires to detect and track information, including temperature and/or moisture content.

The TEG module 110a is shown in FIG. 1 thermally coupled with a first temperature zone 108a and a second temperature zone 108b. For example, the first temperature zone 108a can be an above-ground or exterior surface of the irrigation target 106 and the second temperature zone 108b can be a below-grade, or subsurface soil section of the irrigation target 106. The first and second temperature zones 108a, 108b can exhibit distinct temperatures, which can change over time and for different soil conditions. The difference in temperature between the first and second temperature zones 108a, 108b can be indicative of certain properties of the irrigation target 106, such as whether the irrigation target 106 requires watering.

The TEG module 110a is exposable to the temperature difference of the first and second temperature zones 108a, 108b, and can use the temperature difference in order to control one or more features of an irrigation or associated systems. For example, the TEG module 110a can have at least a hot component 114 that can be thermally coupled to the first temperature zone 108a, and the a cold component 118 that can be thermally coupled to the second temperature zone 108b. The hot and cold components 114, 118 can register a temperature difference ΔT that can be measured between the first and second temperature zones 108a, 108b. The temperature difference can in turn be used by the TEG module 110a to generate a voltage, as described in greater detail below. In some cases, the hot and cold components 114, 118 can be adapted to enhance or maintain the temperature difference between the first and second temperature zones 108a, 108b, such as by using various thermal elements, including lens, mirrors, plates, rods, and the like, contemplated herein. Accordingly, it will be appreciated that the TEG module 110a is shown in FIG. 1 for purposes of illustration and is not a limiting representation of the structure of the TEG modules described herein.

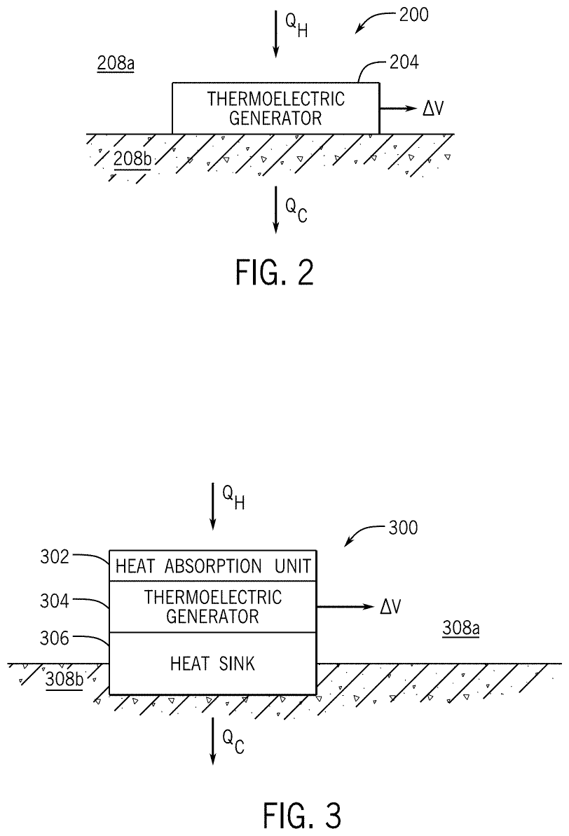

The thermoelectric devices of the present application, including the group of thermoelectric devices 110 of FIG. 1, can be implemented in a variety of manners in order to generate a voltage based on temperature difference of a target environment. FIG. 2 shows a functional diagram of a thermoelectric system 200 which can be used to facilitate the functions of the various thermoelectric devices and modules described herein. For example, the thermoelectric system 200 can employ a thermoelectric generator (TEG) 204 that operates to generate a voltage ΔV in response to a temperature differential. The TEG 204 can be exposed to a first temperature zone 208a and a second temperature zone 208b, which can each exhibit difference temperatures. The TEG module 204 can therefore have a “hot” side through which the TEG 204 receives heat flow Q_{H} corresponding to a hotter or higher temperature of the first temperature zone 208a. The TEG 204 can further emit or release heat flow Q_{C} corresponding to a cooler or lower temperature of the second temperature zone 208b.

The TEG 204 therefore generally uses temperature difference to generate a voltage. In one example, the TEG 204 includes groupings of N-type and/or P-type semiconductors. The N-type and P-type semiconductors can be electrically connected in series and thermally connected in parallel. Such arrangement can facilitate leveraging the Seebeck effect, such that when the TEG module 204 is exposed to a temperature difference of ΔT, it generates a proportional voltage proportional. This also allows the TEG 204 to operate under conditions of no solar irradiance (e.g., in the shade), which makes the TEG 204 superior to conventional solar panels, which rely on solar irradiance. Additionally to alternatively, the TEG 204 can operate using, or as a component of, a Peltier device. Peltier devices are not necessarily designed for voltage generation, and thus can have lower efficiencies, in some circumstances; however, the cost can be lower than other arrangements of the TEG 204.

The thermoelectric generators and modules of the present disclosure can be integrated with features of an outdoor environment, such as the environment 100 of FIG. 1. The thermoelectric generator modules can include various thermal components in order to enhance, modify, or maintain the temperature difference experienced by the thermoelectric module. This can in turn provide a stronger voltage generated by the module, which can be adapted to a wider range of applications. In this regard, FIG. 3 shows a functional diagram of a thermoelectric system 300, including thermal features to enhance the voltage generation of a thermoelectric module. The thermoelectric system 300 can be substantially analogous to the thermoelectric system 200 of FIG. 2. For example, the thermoelectric system 300 can operate to generate a voltage ΔV in response to a temperature differential, and include a thermoelectric generator (TEG) 304, a first temperature zone 308a, and a second temperature zone 308b; redundant explanation of which is omitted here for clarity.

FIG. 3 shows the thermoelectric system 300 as including a heat absorption unit 302. The heat absorption unit 302 is associated with a “hot” side of the TEG 304, and thus is configured to receive a flow of heat Q_{H} associated with the first temperature zone 308a. The heat absorption unit 302 generally operates to concentrate heat and transfer the heat efficiently to the hot side of the TEG 304. For example, the heat absorption unit 302 can be lens, a mirror, a plate, a sphere, and/or combinations and variations thereof that can collect heat in the first temperature zone 308a and the transfer the heat the TEG 304. With the addition of the heat absorption unit 302, the hot side of the TEG 304 can be exposed to a hotter or higher temperature than may otherwise be possible absent the heat absorption unit.

FIG. 3 also shows the thermoelectric system 300 as including the a heat sink 306. The heat sink 306 is associated with a “cold” side of the TEG 304, is thus configured to emit or release a flow of heat Q_{C} into or associated with the second temperature zone 308b. For example, the heat sink 306 can be at least partially arranged within the second temperature zone 308 (e.g., at least partially installed in the soil), and thus be thermally connected with a cooler surrounding environment from that of the heat absorption unit 302. The heat sink 306 generally operates to promote heat dissipation and emission from the TEG 304. This can help lower the temperature of the cold side of the TEG 304. For example, the heat sink 306 can be a rod, bar, plate, and/or variations and combinations thereof can dissipate heat into the second temperature zone 308b. The heat sink 306 can be formed from a metal material to facilitate heat dissipation. With the addition of the heat sink 306, the cold side of the TEG module 304 can generally be colder at a lower temperature than may be otherwise possible absent the heat sink 306.

The heat absorption unit 302 and the heat sink 306 can cooperate to increase a temperature differential experienced by the TEG 304. For example, the heat absorption unit 302 can increase a temperature of the hot side of the TEG 304, while the heat sink 306 can lower a temperature of the cold side of the TEG module 304. With the enhanced temperature differential, the TEG module 304 can generate proportionally greater voltages. The proportionally greater voltages can be used to power more or wider ranges of devices, including different irrigation sprinklers. The greater voltage can also enhance the sensitivity of the system, allowing an associated controller to operate a valve at a wider or different range of thresholds.

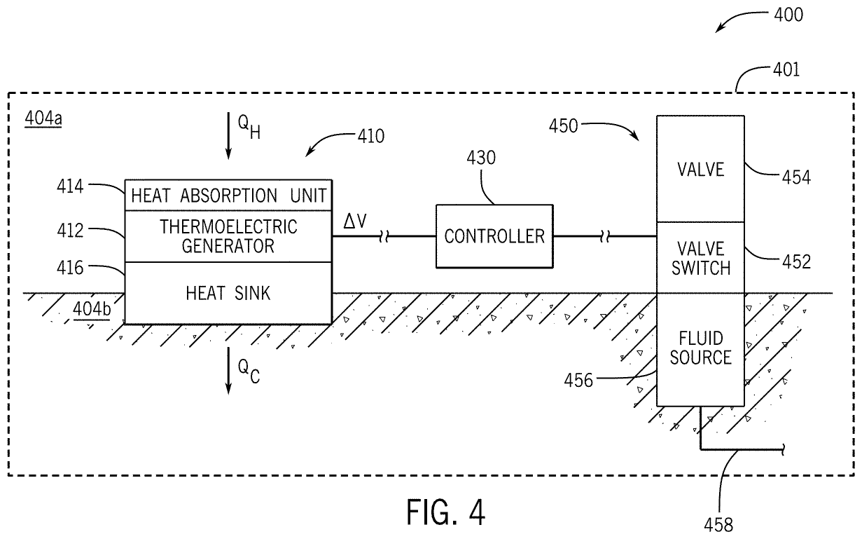

The thermoelectric generators and modules of the present disclosure can be used to control features of an irrigation system, including irrigation sprinklers and associated components. The thermoelectric generator modules can provide a power source to the irrigation features, locally, without reliance on external power sources or solar panels that would require more direct solar irradiance. The thermoelectric generators can also provide information associated with the local environment itself to actuate the irrigation features, such as by providing a voltage or other signals indicative of an ambient condition that corresponds to a requirement of the soil. In this regard, FIG. 4 shows a functional diagram of a thermoelectric system 400 including components of an irrigation system that are at least partially controllable by the thermoelectric module. The thermoelectric system 400 can be substantially analogous to the thermoelectric systems 200 and 300 of FIGS. 2 and 3. For example, the thermoelectric system 400 can generate a voltage ΔV in response to a temperature differential, and include a thermoelectric generator (TEG) 412, a heat absorption unit 414, a heat sink 416 (collectively defining a thermoelectric subassembly 410), and a first temperature zone 404a, and a second temperature zone 404b; redundant explanation of which is omitted here for clarity.

FIG. 4 shows the thermoelectric system 400 as including a controller 430. The controller 430 can include or be a component of one or more control circuitry components that can use a voltage differential in order to generate a signal. For example, the controller 430 can be generally operable to generate a command for controlling an irrigation sprinkler, in response to a voltage meeting or exceeding a threshold value (e.g., including a voltage generated from the thermoelectric subassembly 410. The controller 430 can also be configured as an amplifier or be associated with analogous components, in order to amplify and tune signal, as appropriate, in order to effect a desired operation of an associated valve. The controller 430 can also more generally include any other electrical components to facilitate the various operations described herein, including various antennas to provide remote and wireless data transfer between the thermoelectric system and remote computing system.

The controller 430 can provide an interface between the thermoelectric subassembly 410, or thermoelectric devices more generally, and various components of an irrigation system. In the sample thermoelectric system 400 shown in FIG. 4, the controller 430 provides an interface between the thermoelectric subassembly 410 and an irrigation subassembly 450. The irrigation subassembly 450 can include, define, or be associated with an irrigation sprinkler and/or other device that operates to provide water or other fluids to an environment. The irrigation subassembly 410 can be associated with an irrigation target (e.g., irrigation target 106 of FIG. 1), and can be individually controllable to provide water to the irrigation target. The thermoelectric subassembly 410 can be integrated with the irrigation target and used to provide power and/or other information that is used, in conjunction with the controller 430, to control an operation of the irrigation subassembly 450.

To facilitate the foregoing, the irrigation assembly 450 can include a valve switch 452 that is electrically connected to the controller 430. The valve switch 452 can be responsive to a signal provided by the controller 430. For example, the controller 430 can emit a signal or signals that cause(s) the valve switch to change a state or position or configuration for manipulating an associated component. The valve switch 452 can generally be an electrically actuatable device that is couplable to other components of the irrigation subassembly to facilitate their respective actuation. For example, the irrigation subassembly 450 can include a valve 454 and the valve switch 452 can be coupled to the valve 454. The valve 454 can include various types of valves, including ball valves, globe valves, gate valves, diaphragm valves, butterfly valves, and so on to facilitate fluid control and emission thereof from the irrigation subassembly 450. The valve switch 452 can be coupled to the valve in a manner that facilitates manipulation of the valve 454. For example, the valve switch 452 can operate to cause the valve 454 to transition between a fluidly open configuration (fully allowing fluid emission from the irrigation subassembly 450) and a fluidly closed configuration (fully closing or preventing fluid emission from the irrigation subassembly 450). Additionally or alternatively, the valve switch 452, in conjunction with the signal provided by the controller 430, can cause the valve 454 to exhibit a partially open and/or partially closed configuration, helping to throttle fluid emission from the irrigation subassembly 450.

In this regard, the valve 454 can be fluidly coupled with a fluid source 456 and fluid connection 458. The fluid source 456 is represented schematically in FIG. 4, representative of a source of water (or other fluids or nutrients) provided to the irrigation subassembly 450 for delivery to the irrigation target. The fluid source 456 can be a component of a larger fluid distribution system, for example, in which the fluid source 456 is fluidly coupled to multiple other irrigation subassemblies in a distributed or remote location. The fluid connection 458 can be representative of a fluid connection to a main or distribution line in a larger irrigation system. The fluid connection 458 can also be coupled to a municipal water source or supply; however, this is not required. For example, the fluid connection 458 can be used to fluidly connect the irrigation subassembly 450 to a tank or other water storage apparatus that is isolated from a larger or regional water grid, as may be appropriate in certain rural applications.

FIG. 4 also shows the thermoelectric system 400 as including a functional enclosure 401. As described herein, the thermoelectric devices, modules, assemblies can operate independent of an irrigation system or component, and can thus be stand-alone devices. However, in other embodiments, it may be desirable to integrate the thermoelectric generators or modules and associated components directly with some or all of the irrigation components used to provide water to the irrigation target. For example, a single, integrated unit can be provided that both includes components arranged to generate a voltage or signals, in addition to components that use the signal to deliver water.

The functional enclosure 401 shown in FIG. 4 can encompass the thermoelectric subassembly 450, the control 430, and the irrigation subassembly 450. For example, a single integrated enclosure can define a device that includes the TEG 412, through which the voltage is generated using the temperature differential in the associated environment. The single integrated enclosure can also include the controller 430 therein for processing the generated voltage into the command signals and the like. The single integrated enclosure can also include some or all of the irrigation subassembly 450, such as including the valve switch 452 and a portion of the valve 454. The functional enclosure 401 can be used to provide the thermoelectric system 400 as an integrated package that the user can install directly without necessarily connecting the thermoelectric system 400, electrically, to other external components.

While the functional enclosure 401 is shown in FIG. 4 as including the thermoelectric subassembly 410 and at least some of the irrigation subassembly 450, it will be appreciated that various combinations thereof are contemplated herein. For example, the functional enclosure 401 could encompass the thermoelectric subassembly 410 and the controller 430, which can be electrically coupled to a remote irrigation subassembly 450. Further, while the functional enclosure 401 may be a unitary component, the functional enclosure 401 can also represent a collection of various panels, pieces, covers, and so forth that are coupled to one another to retain the thermoelectric subassembly 410 and/or the controller 430 and/or the irrigation subassembly 450 therein, and/or to also shield some or all of such component from an external environment, as may be appropriate for a given application.

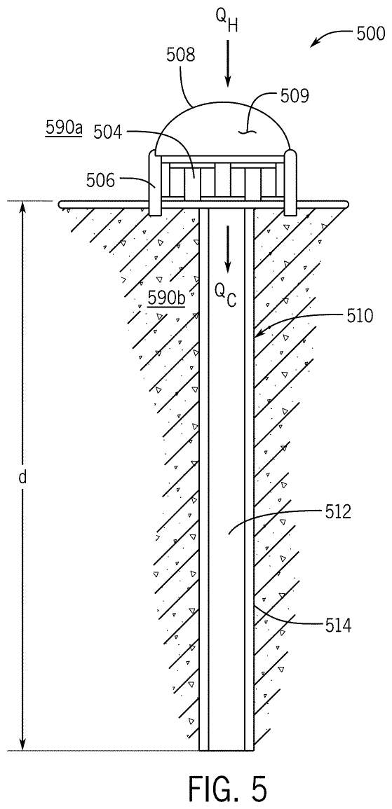

FIGS. 5-9 depict various implementations of thermoelectric modules. The thermoelectric modules of FIGS. 5-9 are substantially analogous to those described herein, operating to generate a voltage in response to exposure to a temperature differential. The thermoelectric generators and modules of the present disclosure can include different combinations and inclusions of thermal components, such as various heat absorption units and heat sinks. The different combinations and inclusion of such thermal components can be adapted to a specific environment of the thermoelectric module, including where a particular range of temperature differential is desired (as can be influenced by different combinations of heat sinks and absorption units). Manufacturing, cost, aesthetics, and other considerations can also influence the specific implementation of the thermoelectric module. As such, it will be appreciated that while FIGS. 5-9 show specific embodiments of such thermal devices, this is for purposes of illustration, and other combinations are contemplated within the scope of the present disclosure.

With reference to FIG. 5, a thermoelectric module 500 is shown. The thermoelectric module 500 can be substantially analogous to any of the thermoelectric modules and devices described herein and include a thermoelectric generator 504, a heat absorption unit 508, and a heat sink 510, redundant explanation of which is omitted for clarity. The thermoelectric module is shown in FIG. 5 as being exposed to a first temperature zone 590a (which can be a surface or ambient temperature) and a second temperature zone 590b (which can be a subsurface or soil temperature).

In the embodiment of FIG. 5, the thermoelectric module 500 can include a housing 506. The housing 506 can be or define a portion of the functional enclosure described herein (e.g., functional enclosure 401 of FIG. 4). The housing 506 can generally enclosure some or all of the thermoelectric generator 504. As such, the housing 506 can provide a barrier between the electrical components of the thermoelectric generator, such as the N- and P-type semiconductors, and an external environment.

FIG. 5 also shows the thermoelectric system 500 with the heat absorption unit 508 including a lens 509. The lens 509 can be mounted to a hot side of the thermoelectric generator 504 and used to collect and optionally concentrate heat of the first temperature zone 590. For example, the lens 509 can define one or more arcuate surfaces that cooperate with one another to direct heat efficiently toward the hot side of the thermoelectric generator 504.

FIG. 5 also shows the thermoelectric system 500 as including the heat sink 510 and a rod 512. The rod can be thermally connected with a cold side of the thermoelectric generator 504 and extend into the second temperature zone (e.g., the soil) by a distance d. For most soil types, 12 inches can be an optimal value for the distance d; however, in other cases, other distances can be sufficient or desired. For example, in other embodiments, the distance d can be less than 12 inches, such as being less than six inches, less than three inches, or less than one inch. In other embodiments, the distance d can be greater than 12 inches, such as being greater than 16 inches, greater than 20 inches, or greater than 24 inches, as may be appropriate for a given application. The deeper the rod extends into the soil, the higher the dissipation effects. As such, the distance d can be determined, in part, by the type of soil, presence of rock, typical climate at the irrigation target, and so on. The rod 512 can also be insulated, and thus is shown in FIG. 5 as including a jacket 514. The jacket 514 can help induce heat exchange near or at the distance d below the surface, where it can be cooler, as opposed to heat exchange across major surface of the rod.

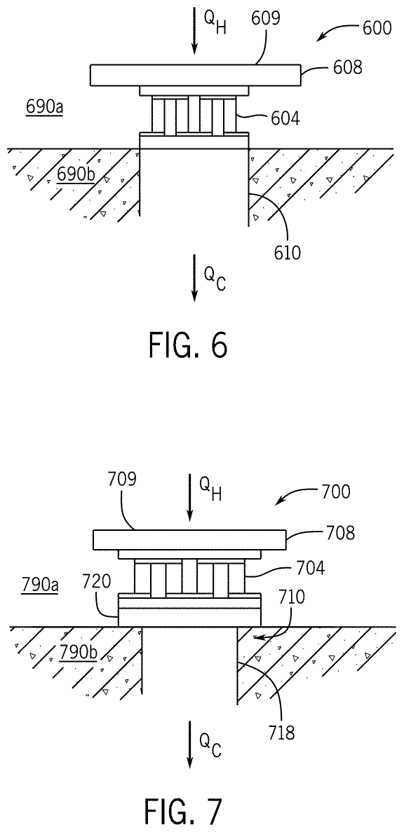

With reference to FIG. 6, a thermoelectric module 600 is shown. The thermoelectric module 600 can be substantially analogous to any of the thermoelectric modules and devices described herein and include a thermoelectric generator 604, a heat absorption unit 608, and a heat sink 610, redundant explanation of which is omitted for clarity. The thermoelectric module is shown in FIG. 6 as being exposed to a first temperature zone 690a (which can be a surface or ambient temperature) and a second temperature zone 690b (which can be a subsurface or soil temperature).

In the embodiment of FIG. 6, the thermoelectric module 600 is shown with the heat absorption unit 608 including a plate 609. The plate 609 can be a blackbody Al (Aluminum) plate that operates to provide heat to the hot side of the thermoelectric device 604. The plate 609 can have substantially flat or smooth outer contour and, in some cases, extend beyond a profile of the thermoelectric device 604. This can increase a surface area of the thermoelectric module 600 that is adapted to receive heat from the first temperature zone 690a, and thus help improve the temperature differential that the thermoelectric device 600 is capable of collecting.

With reference to FIG. 7, a thermoelectric module 700 is shown. The thermoelectric module 700 can be substantially analogous to any of the thermoelectric modules and devices described herein and include a thermoelectric generator 704, a heat absorption unit 708, a heat sink 710, plate 709 redundant explanation of which is omitted for clarity. The thermoelectric module is shown in FIG. 7 as being exposed to a first temperature zone 790a (which can be a surface or ambient temperature) and a second temperature zone 790b (which can be a subsurface or soil temperature).

In the embodiment of FIG. 7, the thermoelectric module 700 with the heat sink 710 including a plate 720 and a rod 718. The plate 720 can be thermally coupled to a cold side of the thermoelectric device 704 and be arranged at least partially within the second temperature zone 790b. The rod 718 can extend from the underside of the plate 720 and further into the soil. The plate 720 can have a larger cross-sectional area than that of the rod and sit on the soil, in certain embodiments. This can increase the heat emission from the cold side of thermoelectric device, for example, without increasing the surface area or length of the rod 718.

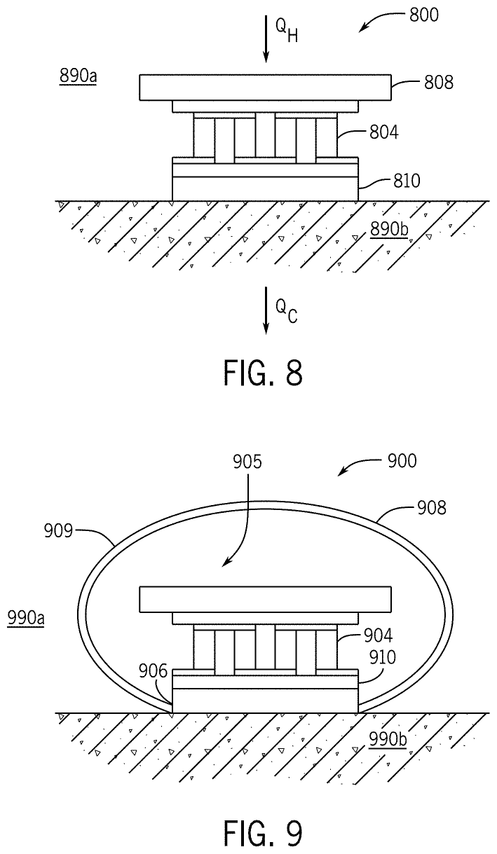

With reference to FIG. 8, a thermoelectric module 800 is shown. The thermoelectric module 800 can be substantially analogous to any of the thermoelectric modules and devices described herein and include a thermoelectric generator 804, a heat absorption unit 808, and a heat sink 810, redundant explanation of which is omitted for clarity. The thermoelectric module is shown in FIG. 8 as being exposed to a first temperature zone 890a (which can be a surface or ambient temperature) and a second temperature zone 890b (which can be a subsurface or soil temperature).

In the embodiment of FIG. 8, the thermoelectric module 800 is shown with the heat sink 810 including a plate 820, without a thermally coupled rod. Based on the soil type and geography it can be undesirable to install a thermoelectric device fully into the ground, such as with a rod or embodiments thereof. In this regard, the thermoelectric device 800 includes a plate 820 that sits adjacent or on the exterior surface of the soil, providing a heat sink in the form of a Al plate with sufficient surface area to encourage heat dissipation from the cold side of the thermoelectric device 804.

With reference to FIG. 9, a thermoelectric module 900 is shown. The thermoelectric module 900 can be substantially analogous to any of the thermoelectric modules and devices described herein and include a thermoelectric generator 904, a heat absorption unit 908, and a heat sink 910, redundant explanation of which is omitted for clarity. The thermoelectric module is shown in FIG. 9 as being exposed to a first temperature zone 990a (which can be a surface or ambient temperature) and a second temperature zone 990b (which can be a subsurface or soil temperature).

In the embodiment of FIG. 9, the thermoelectric module 900 is shown with the heat absorption unit 908 including a sphere 909. The sphere 909 can have an opening 906 that is substantially fitted around the thermoelectric generator 904. The sphere 909 can generally define a hole interior 905, within which the thermoelectric generator 904 resides. The sphere 909 can be a black hollow sphere that is adapted to collect and transfer heat to the hot side of the thermoelectric device 904.

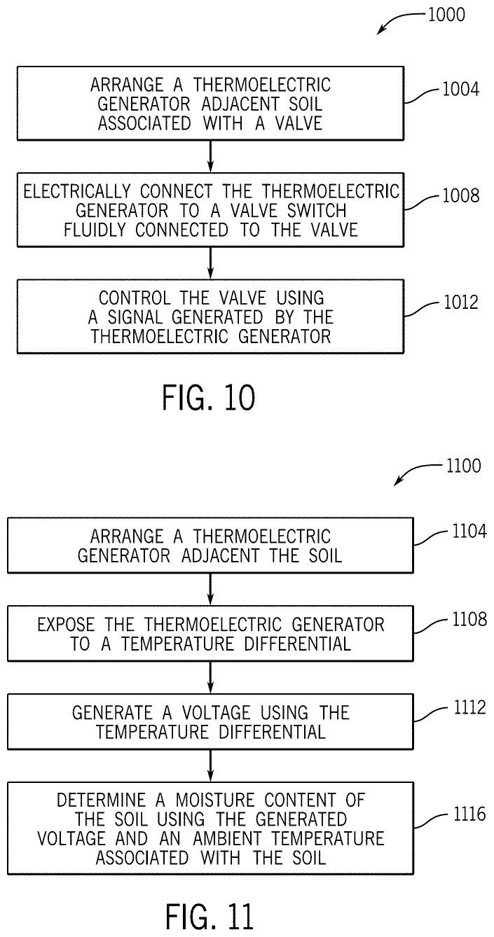

To facilitate the reader's understanding of the various functionalities of the embodiments discussed herein, reference is now made to the flow diagram in FIGS. 10 and 11, which illustrates process 1000 and 1100, respectively. While specific steps (and orders of steps) of the methods presented herein have been illustrated and will be discussed, other methods (including more, fewer, or different steps than those illustrated) consistent with the teachings presented herein are also envisioned and encompassed with the present disclosure.

In this regard, with reference to FIG. 10, process 1000 relates generally to a method for controlling a valve. The process 1000 can be used with any of the thermoelectric devices and systems described herein, for example, such as the systems 200, 300, 400 and/or modules 500, 600, 700, 800, 900, and variations and combinations thereof.

At operation 1004, a thermoelectric generator (TEG) module can be arranged adjacent soil that is associated with a valve. For example and with reference to FIG. 4, the thermoelectric generator 412 can be arranged adjacent soil that is associated with the valve 454. The soil can be associated with the second temperature zone 404b, which can be an irrigation target of the valve 454 or irrigation subassembly 450 more generally. The thermoelectric generator 412 can be associated with the soil, in some cases, using the heat sink 416. For example, the heat sink 416 can be a rod or other feature adapted to extend substantially into the soil. In other cases, the thermoelectric generator 412 can be installed substantially on a surface of the soil and optionally associated with the soil using external attachment structures, including hooks or stakes.

At operation 1008, the TEG module can be electrically connected to a valve switch that is fluidly connected to the valve. For example and with reference to FIG. 4, the thermoelectric generator 412 an be electrically connected to the valve switch 452. For example, the thermoelectric generator can generate a voltage and the valve switch can receive the voltage of signal derived therefrom to control one or more operations of the valve. In some cases, the controller 430 can function as an interface between the thermoelectric generator 412 and the valve switch 452. For example and as described herein, the controller 430 can receive the voltage generated from the thermoelectric generator 412 and use the voltage to generate a command or control signal that can be used to actuate the valve switch 452. In this regard, at operation 1012, the valve 454 can be controlled using a signal generated by the TEG module, via the controller 430.

With reference to FIG. 11, process 1100 relates generally to a method for measuring soil moisture. The process 1100 can be used with any of the thermoelectric devices and systems described herein, for example, such as systems 200, 300, 400 and/or modules 500, 600, 700, 800, 900, and variations and combinations thereof.

At operation 1104, a thermoelectric generator (TEG) module can be arranged adjacent the soil. For example and with reference to FIG. 2, the thermoelectric generator 204 can be arranged adjacent soil. For example, the thermoelectric generator 204 can be thermally connected to the second temperature zone 208b so that the cold side of the generator 204 is capable of dissipating heat at least partially into the soil.

At operation 1108, the TEG module can be exposed to a temperature differential. For example and with reference to FIG. 2, the thermoelectric module 204 can be exposed to a temperature of the first temperature zone 208a at or near a hot side of the thermoelectric module 204. The thermoelectric module 204 can further be exposed to a temperature of the second temperature zone 208b at or near a cold side of the thermoelectric module 204. The temperatures of the first and second temperature zones 208a, 208b can be different, thus exposing the thermoelectric generator 204 to a temperature differential.

At operation 1112, a voltage can be generated using the temperature differential. For example and with reference to FIG. 2, the thermoelectric generator 204 can employ various thermal and electrical configurations to generate a voltage in response to the temperature differential of the first and second temperature zone 204a, 204. For example and as described herein, the thermoelectric generator 204 can include various N- and P-type semiconductors that are electrically connected in series and thermally connected in parallel. The semiconductors cooperate to generate a voltage, according to the Seebeck effect, which can be proportional to the temperature differential. Additionally or alternatively, the thermoelectric device 204 can operate using a Peltier device.

At operation 1116, a moisture content of the soil can be determined using the generated voltage and an ambient temperature associated with the soil. For example and with reference to FIG. 2, the moisture content of the soil 104 can be a function of the voltage generated by the thermoelectric device and the ambient temperature. The thermoelectric device or associated equipment can be calibrated using linear or non-linear regression. The relationship between the soil moisture, temperature, and voltage can be provided to the user in the form of a chart/table or a mathematical equation, and can be customized to a particular type of soil. The thermoelectric generator 204 can thus be a moisture sensor that can be used independent of irrigation system components or features. In some cases, however, the generator can be adapted to provide the moisture data to an irrigation component, controller, or other element, in order to control the irrigation component based on local conditions.

Other examples and implementations are within the scope and spirit of the disclosure and appended claims. For example, features implementing functions may also be physically located at various positions, including being distributed such that portions of functions are implemented at different physical locations. Also, as used herein, including in the claims, “or” as used in a list of items prefaced by “at least one of” indicates a disjunctive list such that, for example, a list of “at least one of A, B, or C” means A or B or C or AB or AC or BC or ABC (i.e., A and B and C). Further, the term “exemplary” does not mean that the described example is preferred or better than other examples.

The foregoing description, for purposes of explanation, uses specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art that many modifications and variations are possible in view of the above teachings.

What is claimed is:

1. A device for remotely and automatically operating a valve, the device comprising:
a thermoelectric generator (TEG);
a heat absorption unit;
a heat sink;
a control circuit; and
a switch operably connected to the valve.

2. The device of claim 1, wherein the TEG, control circuit, and switch are electrically connected.

3. The device of claim 1, wherein the TEG, absorption unit, and heat sink are thermally connected.

4. The device of claim 1, wherein the valve is fluidly connected to an irrigation sprinkler.

5. The device of claim 1, wherein the TEG comprises N- or P-type semiconductors.

6. The device of claim 5, wherein the N- or P-type semiconductors are connected in parallel.

7. The device of claim 1, wherein the heat absorption unit is selected from one or more of a lens or a mirror for concentrating solar radiation on a hot side of the TEG.

8. The device of claim 1, wherein the heat absorption unit comprises a black hollow sphere fitted around the TEG for absorbing visible and non-visible light.

9. The device of claim 1, wherein the heat sink comprises a rod configured to be inserted into soil.

10. The device of claim 1, further comprising a battery electrically connected to the TEG for storing electricity.

11. A method for controlling a valve, the method comprising:
arranging a thermoelectric generator (TEG) adjacent soil that is associated with a valve;
electrically connecting the TEG to a valve switch fluidly connected to the valve; and
controlling the valve using a signal generated by the TEG.

12. The method of claim 11, wherein:
the method further comprises:
exposing the TEG to a temperature differential; and
generating a voltage using the temperature differential; and
the signal is based at least in part on the generated voltage.

13. The method of claim 12, wherein:
the method further comprises inserting a heat sink into the soil, the heat sink thermally coupled to the TEG;
the TEG is thermally connected to a heat absorption unit; and
the temperature differential is defined between the heat sink and the heat absorption unit.

14. The method of claim 11, wherein a controller is positioned between the TEG and valve switch, and in electrical communication with the TEG and valve switch.

15. The method of claim 11, wherein the valve is in fluid connection with an irrigation sprinkler.

16. The method of claim 11, wherein a controller is wirelessly connected to multiple thermoelectric devices and generates a pulse for the valve switch based on the collective information received from multiple TEGs.

17. A method for measuring soil moisture, the method comprising:
arranging a thermoelectric generator (TEG) adjacent the soil;
exposing the TEG to a temperature differential;
generating a voltage using the temperature differential; and
determining a moisture content of the soil using the generated voltage and an ambient temperature associated with the soil.

18. The method of claim 17, wherein the operation of determining comprises calibrating the voltage to the moisture content using a linear or non-linear regression, wherein the moisture content is a function of the generated voltage and the ambient temperature.

19. The method of claim 17, further comprising transmitting a signal including information associated with the moisture content to a remote device.

20. The method of claim 17, wherein:
the method further comprises thermally associating the TEG with a heat sink arranged at least partially within the soil;
the TEG includes a heat absorption unit arranged opposite the heat sink; and
the temperature differential is defined between the heat sink and the heat absorption unit.
